(19) United States
(12) Patent Application Publication
(10) Pub. No.: US 2015/0221576 A1
(43) Pub. Date: Aug. 6, 2015

(54) Heat Dissipation Structure for Semiconductor Element

(71) Applicant: Asia Vital Components Co., Ltd., New Taipei City (TW)

(72) Inventors: Chih-Yeh Lin, New Taipei City (TW); Chih-Ming Chen, New Taipei City (TW)

(73) Assignee: Asia Vital Components Co., Ltd., New Taipei City (TW)

(21) Appl. No.: 14/169,408

(22) Filed: Jan. 31, 2014

(51) Int. Cl. H01L 23/373

(52) U.S. Cl. CPC H01L 23/3736; H01L 23/3735; H01L 23/3733

(57) ABSTRACT

A heat dissipation structure for semiconductor element includes a semiconductor element and a covering. The covering has a first side and an opposite second side and is formed on the second side with a heat radiation layer. The covering is externally covered on one side of the semiconductor element with the first side of the covering attached to the covered side of the semiconductor. By attaching the covering to one side of the semiconductor element, heat emitted by the semiconductor element during operation can be more quickly absorbed by the covering and radiated from the heat radiation layer into ambient environment to avoid heat accumulation on the semiconductor element.

### FIELD OF THE INVENTION

The present invention relates to a heat dissipation structure for semiconductor element, and more particularly to a heat dissipation structure that enhances the semiconductor element's heat dissipation performance via natural heat radiation.

### BACKGROUND OF THE INVENTION

The currently available mobile electronic devices, such as slim-type notebook computers, tablet computers, smartphones and so on, all have constantly increased operation speed, which leads to largely increased heat produced by the semiconductor chip of the internal computation execution unit of the electronic mobile devices. On the other hand, all the current mobile electronic devices have constantly reduced overall thickness to enable convenient portability thereof. Further, to guard against invasion by foreign matters and external moisture, the mobile electronic devices are usually provided with only a headphone jack and necessary connector jacks without other openings communicable with an external space for air convection. Due to the largely reduced overall thickness of the devices, the heat produced by the computation execution unit and the battery inside the mobile electronic devices just could not be quickly dissipated into external environment. The closed narrow internal space of the mobile electronic devices also causes difficulty in the occurrence of air convection, so that heat tends to accumulate or gather inside the mobile electronic devices to seriously affect the devices' working efficiency or cause a crashed computer due to overheating. In some worse conditions, the semiconductor chip is subjected to burnout due to overheating.

Some passive heat dissipation elements, such as heat spreaders, vapor chambers, heat sinks and the like, have been tried for use inside the mobile electronic devices to dissipate heat. To use with the current mobile electronic devices that have largely reduced overall thickness and highly limited internal space, the above-mentioned heat dissipation elements must also have highly reduced overall thickness. As a result, the wick structures and vapor passages in the thickness-reduced heat spreaders and vapor chambers must also have reduced sizes, which results in lowered working efficiency of the heat spreaders and vapor chambers in terms of their general heat transfer capability, preventing the devices' heat dissipation performance from being effectively upgraded. In brief, the conventional heat spreaders and vapor chambers all fail to effectively remove or dissipate the heat from the mobile electronic devices when the latter's internal computation execution units have excessively high power. It is therefore the most important target of mobile electronic device manufacturers to work out an effective way for dissipating heat from a closed narrow space.

### SUMMARY OF THE INVENTION

A primary object of the present invention is to provide a heat dissipation structure for semiconductor element that enhances the semiconductor element's heat dissipation performance via natural heat radiation.

To achieve the above and other objects, the heat dissipation structure for semiconductor element according to the present invention includes a semiconductor element and a covering.

The covering has a first side and an opposite second side and is formed on the second side with a heat radiation layer. The covering is externally covered on one side of the semiconductor element with the first side of the covering attached to the covered side of the semiconductor.

The present invention is characterized by attaching a covering having high thermal transfer efficiency and good heat dissipation performance to an outer side of a semiconductor element and providing a heat radiation layer on one side of the covering opposite to the semiconductor element to enable largely enhanced heat radiation efficiency. With these arrangements, the heat emitted by the semiconductor element located in the closed narrow space of a mobile electronic device during operation can still be effectively dissipated through natural heat radiation and heat convection, so that the semiconductor element can have largely increased heat dissipation performance.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled perspective view of a heat dissipation structure for semiconductor element according to a first embodiment of the present invention;

FIG. 2 is an assembled sectional view of the heat dissipation structure of FIG. 1; and

FIG. 3 is an assembled sectional view of a heat dissipation structure for semiconductor element according to a second embodiment of the present invention.

### DETAILED DESCRIPTION OF THE PREFERRED EMBODIMENTS

The present invention will now be described with some preferred embodiments thereof and with reference to the accompanying drawings. For the purpose of easy to understand, elements that are the same in the preferred embodiments are denoted by the same reference numerals.

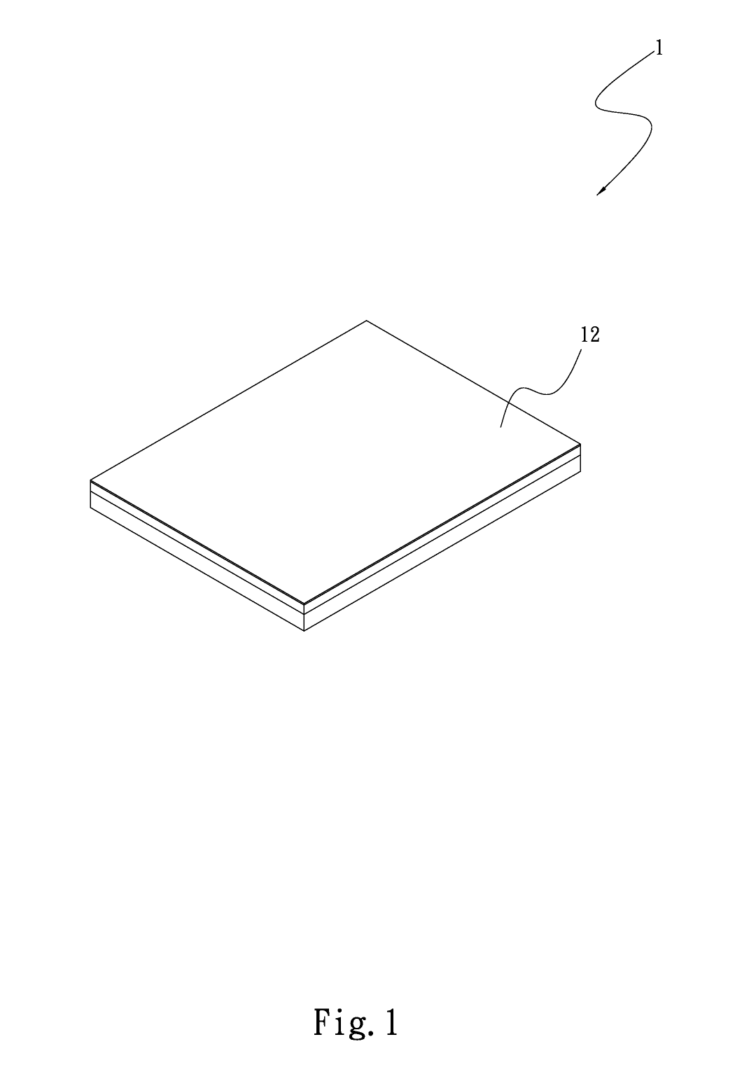

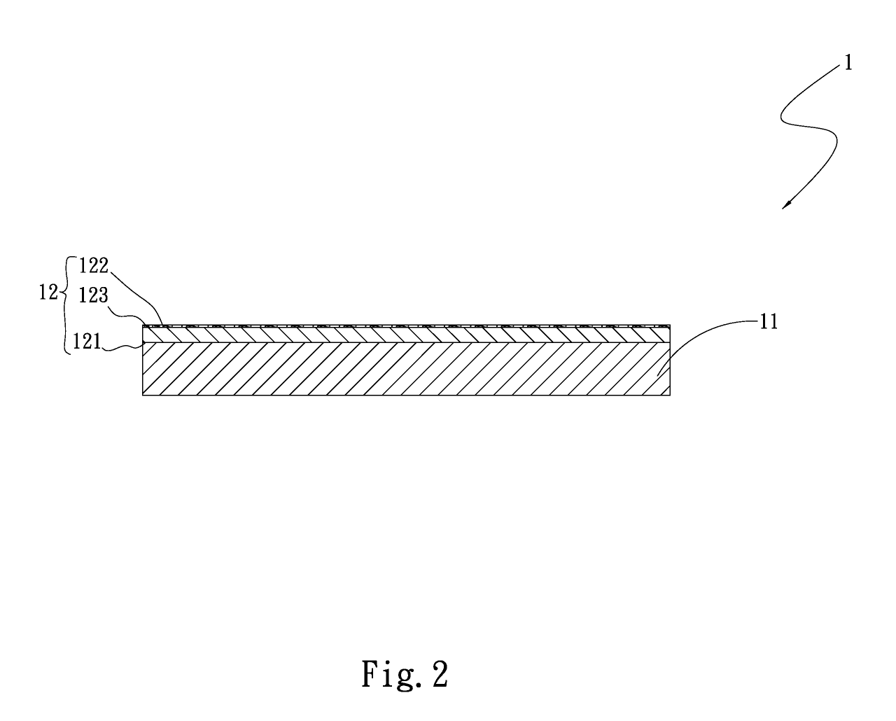

Please refer to FIGS. 1 and 2 that are assembled perspective and sectional views, respectively, of a heat dissipation structure for semiconductor element according to a first embodiment of the present invention. For the purpose of clarity and conciseness, the present invention is also briefly referred to as the heat dissipation structure and generally denoted by reference numeral 1 herein. As shown, the heat dissipation structure 1 in the first embodiment includes a semiconductor element 11 and a covering 12. The covering 12 has a first side 121, an opposite second side 122 and a heat radiation layer 123. The covering 12 externally covers one side of the semiconductor element 11 with the first side 121 attached to the covered side of the semiconductor element 11. The heat radiation layer 123 is formed on the second side 122 of the covering 12. The covering 12 can be made of copper, aluminum, or a composite material made from copper and aluminum. With the first side 121 of the covering 12 attached to the semiconductor element 11, heat emitted by the semiconductor element 11 during operation can be quickly transferred from the semiconductor element 11 to the covering 12.

The first side 121 of the covering 12 can be attached to the semiconductor element 11 by glue bonding or medium-free diffusion bonding.

The heat radiation layer 123 can be of a porous structure, a nanostructure, a porous ceramic structure, a porous graphite structure, a high-radiation ceramic structure, or a high-rigidity ceramic structure. The porous structure can be formed on the second side 122 of the covering 12 by micro arc oxidation (MAO), plasma electrolytic oxidation (PEO), anodic spark deposition (ASD), or anodic oxidation by spark deposition (ANOF).

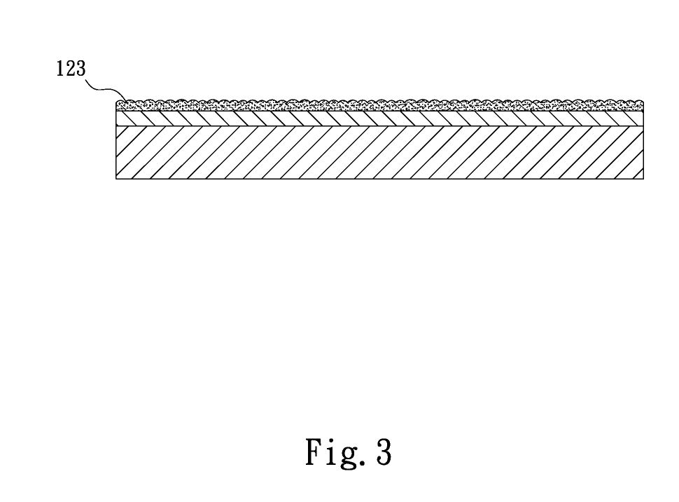

FIG. 3 is an assembled sectional view of a heat dissipation structure for semiconductor element according to a second embodiment of the present invention. As shown, the second embodiment is structurally similar to the first embodiment, except that it has a heat radiation layer 123 being a dimpled structure formed by shot peening.

In both of the first and the second embodiment, the heat radiation layer 123 is in a black color, a near-black color, or any dark color.

The present invention is developed mainly to enhance the heat dissipation performance of the semiconductor element 11 through natural heat radiation. This object is achieved by providing the covering 12 having the heat radiation layer 123 and attaching the first side of the covering 12 to one side of the semiconductor element 11. Further, the heat radiation layer 123 is black-colored and formed on the opposite second side 122 of the covering 12 facing away from the semiconductor element 11 to provide a large heat dissipation contact surface and upgraded heat radiation efficiency.

The present invention applies radiation heat transfer to heat dissipation. As it is known, both heat conduction and heat convection require a physical matter as a heat transfer medium to achieve heat energy propagation. However, unlike the heat conduction and heat convection, heat radiation propagates heat energy directly without the need of any heat transfer medium, and is therefore suitable for use in a closed room having very limited heat dissipation space to transfer internally produced heat to an outer casing of, for example, a mobile electronic device, for heat exchange with ambient air.

Heat radiation means the energy radiated by matters in the form of electromagnetic waves. Electromagnetic waves propagate at the speed of light without the need of a transmission medium. All matters continuously emit heat radiation and also absorb heat radiation from external environment. A matter's ability to emit heat has relation to the matter's surface temperature, color and coarseness. The present invention employs the above-mentioned principles to provide the heat radiation layer 123 with good natural heat radiation ability. That is, the heat radiation layer 123 has increased heat dissipation area and enables upgraded heat dissipation efficiency. In addition to the temperature, the heat radiation intensity of a matter's surface also has relation to the matter's surface properties. For example, a matter having a black-colored surface tends to absorb and emit heat radiation more easily. Therefore, the heat radiation layer 123 of the present invention is black or black-colored to further enhance its heat radiation efficiency.

The present invention has been described with some preferred embodiments thereof and it is understood that many changes and modifications in the described embodiments can be carried out without departing from the scope and the spirit of the invention that is intended to be limited only by the appended claims.

1. A heat dissipation structure for semiconductor element, comprising a semiconductor element and a covering; the covering having a first side and an opposite second side and being formed on the second side with a heat radiation layer; and the covering being externally covered on one side of the semiconductor element with the first side of the covering attached to the covered side of the semiconductor; and
wherein the heat radiation layer is of a dimpled structure formed on the second side of the covering by shot peening.

2. The heat dissipation structure for semiconductor element as claimed in claim 1, wherein the covering is made of a material selected from the group consisting of copper, aluminum, and a composite material made from copper and aluminum.

3. The heat dissipation structure for semiconductor element as claimed in claim 1, wherein the covering is attached at the first side to one side of the semiconductor element in a manner selected from the group consisting of glue bonding and medium-free diffusion bonding.

4. The heat dissipation structure for semiconductor element as claimed in claim 1, wherein the heat radiation layer is of a structure selected from the group consisting of a porous structure and a nanostructure.

5. The heat dissipation structure for semiconductor element as claimed in claim 1, wherein the heat radiation layer is of a porous structure formed on the second side of the covering by a process selected from the group consisting of micro arc oxidation (MAO), plasma electrolytic oxidation (PEO), anodic spark deposition (ASD), and anodic oxidation by spark deposition (ANOF).

6. (canceled)

7. The heat dissipation structure for semiconductor element as claimed in claim 1, wherein the heat radiation layer is of a structure selected from the group consisting of a porous ceramic structure and a porous graphite structure.

8. The heat dissipation structure for semiconductor element as claimed in claim 1, wherein the heat radiation layer has a color selected from the group consisting of a black color, a near-black color, and any dark colors.

9. The heat dissipation structure for semiconductor element as claimed in claim 1, wherein the heat radiation layer is of a structure selected from the group consisting of a high-radiation ceramic structure and a high-rigidity ceramic structure.

10. The heat dissipation structure for semiconductor element as claimed in claim 2, wherein the heat radiation layer has a color selected from the group consisting of a black color, a near-black color, and any dark colors.

11. The heat dissipation structure for semiconductor element as claimed in claim 3, wherein the heat radiation layer has a color selected from the group consisting of a black color, a near-black color, and any dark colors.

12. The heat dissipation structure for semiconductor element as claimed in claim 4, wherein the heat radiation layer has a color selected from the group consisting of a black color, a near-black color, and any dark colors.

13. The heat dissipation structure for semiconductor element as claimed in claim 5, wherein the heat radiation layer has a color selected from the group consisting of a black color, a near-black color, and any dark colors.

14. The heat dissipation structure for semiconductor element as claimed in claim 6, wherein the heat radiation layer has a color selected from the group consisting of a black color, a near-black color, and any dark colors.

15. The heat dissipation structure for semiconductor element as claimed in claim 7, wherein the heat radiation layer has a color selected from the group consisting of a black color, a near-black color, and any dark colors.
